(19) United States
(12) Patent Application Publication
(10) Pub. No.: US 2015/0197852 A1
(43) Pub. Date: Jul. 16, 2015

(54) PLASMA PROCESSING APPARATUS AND PLASMA-UNIFORMITY CONTROL METHOD

(71) Applicant: Taiwan Semiconductor Manufacturing Co., Ltd., Hsin-Chu (TW)

(72) Inventors: Pei-Nung CHEN, Hsinchu City (TW); Hsu-Shui LIU, Pingjhen City (TW)

(73) Assignee: Taiwan Semiconductor Manufacturing Co., Ltd., Hsin-Chu (TW)

(21) Appl. No.: 14/153,430

(22) Filed: Jan. 13, 2014

(51) Int. Cl. C23C 16/50; H01L 21/285; C23C 16/509; C23C 16/455; C23C 16/503; H01L 21/3065; H01L 21/683

(52) U.S. Cl. CPC C23C 16/50; H01L 21/3065; H01L 21/28556; H01L 21/6833; C23C 16/455; C23C 16/503; C23C 16/509

(57) ABSTRACT

Embodiments of a plasma density distribution control method and a plasma processing apparatus are provided. The plasma processing apparatus includes an electrostatic chuck positioned in a processing chamber thereof The electrostatic chuck includes a number of power electrodes for controlling the plasma in the processing chamber, and the power electrodes are separated from and movable relative to each other. Since the distances between the plasma and each of the power electrodes are adjustable, the plasma density in the processing chamber can thus be tunable by zone. Therefore, the uniformity of the plasma density in the processing chamber can be improved. Further, the power electrodes can be driven by a single electrical signal. Therefore, the cost and system complexity of the plasma processing apparatus can be reduced.

### BACKGROUND

A plasma processing apparatus for processing a substrate, such as a semiconductor wafer by using plasma has been used to manufacture a semiconductor device or the like. The plasma processing apparatus includes, for example, a plasma etching apparatus or a plasma-enhanced chemical vapor deposition (PECVD) apparatus.

In plasma processing, the substrate to be processed is placed in a vacuumed processing chamber. Afterwards, plasma is generated in the processing chamber such that ions and electrons are generated as a result of the plasma discharge applied to the surface of the substrate.

In semiconductor fabrication, there is a trend towards using larger wafer for enhancing productivity. However, with an enlargement of the semiconductor object size, the volume of the processing chamber also increases. There is a challenge in processing the larger wafer in such a large processing chamber.

### BRIEF DESCRIPTION OF THE DRAWINGS

For a more complete understanding of the illustrative embodiments and the advantages thereof, reference is now made to the following descriptions taken in conjunction with the accompanying drawings.

FIG. 1 is a schematic diagram of a plasma processing apparatus, in accordance with some embodiments.

FIG. 2 is a cross-sectional view of an electrostatic chuck of a plasma processing apparatus, in accordance with some embodiments.

FIG. 3 is a cross-sectional view of an electrostatic chuck of a plasma processing apparatus, in accordance with some embodiments.

FIG. 4A and FIG. 4B are schematic diagrams of an electrode unit in FIG. 3 and a driving mechanism in FIG. 1, in accordance with some embodiments.

FIG. 5 is a flow chart of a plasma-uniformity control method, in accordance with some embodiments.

### DETAILED DESCRIPTION OF THE ILLUSTRATIVE EMBODIMENTS

The making and using of various embodiments of the disclosure are discussed in detail below. It should be appreciated, however, that the various embodiments can be embodied in a wide variety of specific contexts. The specific embodiments discussed are merely illustrative, and do not limit the scope of the disclosure.

It is to be understood that the following disclosure provides many different embodiments, or examples, for implementing different features of the disclosure. Specific examples of components and arrangements are described below to simplify the present disclosure. These are, of course, merely examples and are not intended to be limiting. Moreover, the performance of a first process before a second process in the description that follows may include embodiments in which the second process is performed immediately after the first process, and may also include embodiments in which additional processes may be performed between the first and second processes. Various features may be arbitrarily drawn in different scales for the sake of simplicity and clarity. Furthermore, the formation of a first feature over or on a second feature in the description may include embodiments in which the first and second features are formed in direct or indirect contact.

Some variations of the embodiments are described. Throughout the various views and illustrative embodiments, like reference numbers are used to designate like elements. It is understood that additional operations can be provided before, during, and after the method, and some of the operations described can be replaced or eliminated for other embodiments of the method.

Embodiments of a plasma processing apparatus are provided. A plasma process such as a plasma etching process or plasma-enhanced chemical vapor deposition (PECVD) process can be executed by the plasma processing apparatus.

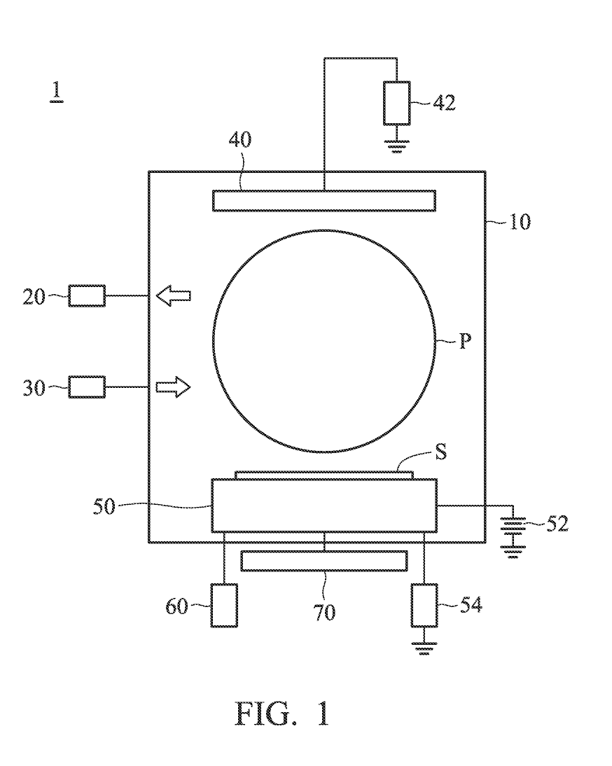

FIG. 1 is a schematic diagram of a plasma processing apparatus 1 according to some embodiments of the disclosure. The plasma processing apparatus 1 includes a processing chamber 10, a gas-supply means 30, and an electrostatic chuck (ESC) 50. In some embodiments, the plasma processing apparatus 1 further includes an air-exhaust means 20, a plasma generation unit 40, a fluid-supply means 60, and/or a driving mechanism 70.

The processing chamber 10 forms a three-dimensional space, such as a cylindrical or cubic space. The air-exhaust means 20 and the gas-supply means 30 are connected to a wall of the processing chamber 10, as shown in FIG. 1, in accordance with some embodiments. The air-exhaust means 20 and the gas-supply means 30 respectively include a gas pipe, a valve, and a pump (not shown) for gas delivery in some embodiments. The gas in the processing chamber 10 can be exhausted via the air-exhaust means 20 to reach vacuum state in the processing chamber 10. A process (reactant) gas can be introduced into the processing chamber 10 via the gas-supply means 30. The process gas can be used as a plasma source for the plasma process.

As shown in FIG. 1, the plasma generation unit 40 and the electrostatic chuck 50 are positioned in the processing chamber 10 and separated from each other, in accordance with some embodiments. The plasma generation unit 40 is driven by a radio frequency (RF) generator 42 to excite the process gas and generate ion plasma P in the processing chamber 10. The electrostatic chuck 50 is used for holding a substrate S, such as a semiconductor wafer, in the processing chamber 10.

In some embodiments, the plasma processing apparatus 1 includes a direct current (DC) power supply 52 and an electrical power supply 54. The electrostatic chuck 50 is driven by the direct current power supply 52 to provide an electrostatic attraction to the substrate S, and the substrate S can be secured on the electrostatic chuck 50. In some embodiments, the electrostatic chuck 50 is driven by the electrical power supply 54 to control the plasma P in the processing chamber 10.

The electrical power supply 54 may supply an alternating current (AC) signal or DC signal. As the electrical power supply 54 supplies an AC signal, such as an RF signal, the electrostatic chuck 50 works with the plasma generation unit 40 to generate the plasma P and control the ionization rate of the plasma P. As the electrical power supply 54 supplies a DC signal, the electrostatic chuck 50 generates a bias to enhance the directionality of the plasma P. As a result, the plasma density distribution in the processing chamber 10 is controlled.

In some embodiments, the electrical power supply 54 and the radio frequency generator 42 are operated independently. In some embodiments, the radio frequency generator 42 and the plasma generation unit 40 are not provided, and the electrostatic chuck 50 generates the plasma P alone.

As shown in FIG. 1, the fluid-supply means 60 is connected to the electrostatic chuck 50, in accordance with some embodiments. The fluid-supply means 60 includes a gas pipe, a liquid pipe, valves, and a pump (not shown) for fluid delivery in some embodiments. The fluid-supply means 60 supplies one or more gas medium and/or one or more fluid medium to the electrostatic chuck 50 for maintaining the temperature of the substrate S during the plasma process. In some embodiments, the driving mechanism 70 is positioned below and connected to the electrostatic chuck 50 for moving one or more parts thereof. The driving mechanism 70 may be disposed in or outside of the processing chamber 10.

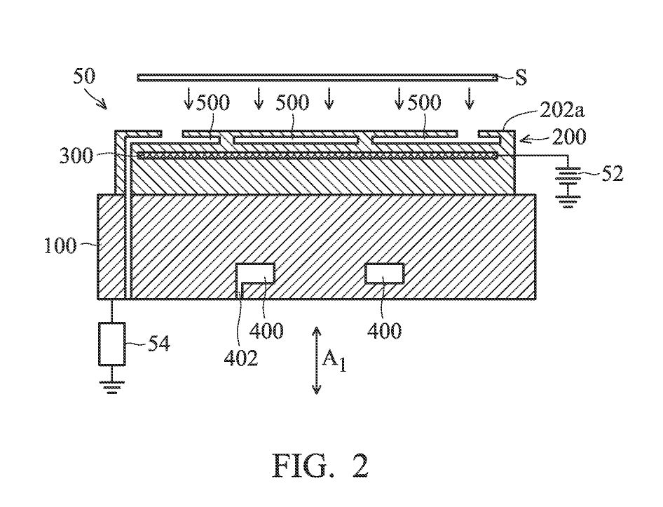

FIG. 2 is a cross-sectional view of the electrostatic chuck 50 of the plasma processing apparatus 1 in FIG. 1 according to some embodiments. Referring to FIG. 1 and FIG. 2, the electrostatic chuck 50 includes a stage 100, a dielectric body 200, and an electrode 300. In some embodiments, the electrostatic chuck 50 further includes a coolant chamber 400 and/or a gas passage 500.

In some embodiments, the stage 100 is configured to support the dielectric body 200 in the processing chamber 10. The dielectric body 200 has a top surface 202a for receiving the substrate S. In some embodiments, the electrode 300 is positioned within the dielectric body 200 and electrically connected to the direct current power supply 52. The electrode 300 is driven by the direct current power supply 52 to apply an electrostatic attraction to the substrate S, therefore preventing movement of the substrate S on the top surface 202a.

In some embodiments, the dimensions and/or the shape of the dielectric body 200 and the electrode 300 substantially match those of the substrate S. In some embodiments, the dielectric body 200 is made of insulating or dielectric material, such as ceramic. The electrode 300 is made of conductive material, such as metal.

In some embodiments, the coolant chamber 400 is formed in the stage 100. A coolant is introduced through, for example, a coolant pipe 402 into the coolant chamber 400. The coolant, such as water, cools the substrate S by flowing through the stage 100, therefore the temperature of the substrate S can be controlled to a desired temperature.

As shown in FIG. 2, the gas passage 500 is formed in the dielectric body 200 and the stage 100, in accordance with some embodiments. A heat transfer medium is supplied to a rear surface of the substrate S through the gas passage 500. For example, the heat transfer medium includes a helium (He) gas, argon (Ar) gas, or the like. Accordingly, the heat transfer medium cools the substrate S and maintains a uniform temperature thereof. In some embodiments, the coolant pipe 402 and the gas passage 500 are connected to the fluid-supply means 60 (as shown in FIG. 1) which provides the coolant and the heat transfer medium to the electrostatic chuck 50.

In some embodiments, the stage 100 also operates as a plasma controlling electrode while electrically connecting to the electrical power supply 54 (as shown in FIG. 1) as described above. As the electrical power supply 54 applies an AC signal or DC signal to the stage 100, the electrical power supply 54 can generate plasma or a bias. Therefore, the plasma density distribution in the processing chamber 10 is controlled. In some embodiments, the stage 100 is made of conductive material. For example, the stage 100 is made of a metal material such as aluminum (Al).

In some embodiments, the stage 100 is coupled with the driving mechanism 70, such as a motor or cylinder (not shown in FIG. 2). Accordingly, the stage 100 can be moved by the driving mechanism 70 along a first axis A1 (substantially perpendicular to the substrate S) for adjusting the distance between the stage 100 and the plasma P.

However, the stage 100 having a one-piece structure (FIG. 2) may have difficulty achieving uniform plasma density distribution in the processing chamber 10. For example, the density of the plasma P in the area close to the center of the substrate S may be higher, and the density of the plasma P in the area adjacent to the edge of the substrate S may be lower, as shown in FIG. 1, due to the originally non-uniform distribution of the process gases in the processing chamber. Therefore, it is desirable to find an alternative plasma processing apparatus achieving a more uniform plasma density distribution.

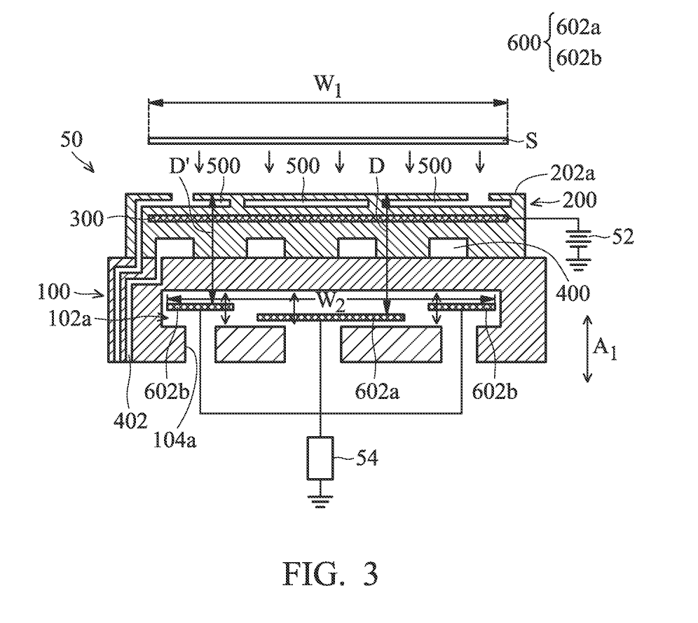

FIG. 3 is a cross-sectional view of an electrostatic chuck 50 of the plasma processing apparatus 1 in FIG. 1 according to some embodiments. Referring to FIG. 1 and FIG. 3, the electrostatic chuck 50 includes a stage 100, a dielectric body 200, an electrode 300, and an electrode unit 600. In some embodiments, the electrostatic chuck 50 further includes a coolant chamber 400 and a gas passage 500.

In some embodiments, the stage 100 is configured to support the dielectric body 200 in the processing chamber 10. The dielectric body 200 has a top surface 202a for receiving the substrate S. In some embodiments, the electrode 300 is positioned within the dielectric body 200 and electrically connected to the direct current power supply 52. The functions and material of the dielectric body 200 and the electrode 300 are similar to or the same as the aforesaid embodiments, and thus are not described again.

In some embodiments, the coolant chamber 400 is formed in the dielectric body 200. A coolant is introduced through, for example, a coolant pipe 402 into the coolant chamber 400. The coolant, such as water, cools the substrate S by flowing through the dielectric body 200, therefore the temperature of the substrate S can be controlled to a desired temperature.

In some embodiments, an intermediate layer with the coolant chamber 400 formed therein can be disposed between the stage 100 and the dielectric body 200. The intermediate layer can be made of insulating or dielectric material, such as ceramic.

The structure and the functions of the gas passage 500 are similar to or the same as the aforesaid embodiments, and thus are not described again.

As shown in FIG. 3, the stage 100 includes a hollow space 102a with the electrode unit 600 disposed therein, in accordance with some embodiments. The electrode unit 600 includes a number of power electrodes 602a and 602b separated from each other in some embodiments. The positions of the power electrodes 602a and 602b correspond to the center and edge of the substrate S, respectively. In some embodiments, the dimensions of the electrode unit 600 correspond to those of the substrate S. For example, the width W1 of the substrate S is substantially equal to the width W2 of the electrode unit 600.

In some embodiments, the power electrodes 602a and 602b are electrically connected to the single electrical power supply 54 (as shown in FIG. 1) for controlling the plasma P in the processing chamber 10. In some embodiments, the plasma processing apparatus 1 includes a number of electrical power supplies 54 electrically connecting to and driving the power electrodes 602a and 602b, respectively. In some embodiments, the electrical power supply 54 supplies RF signals or DC signals.

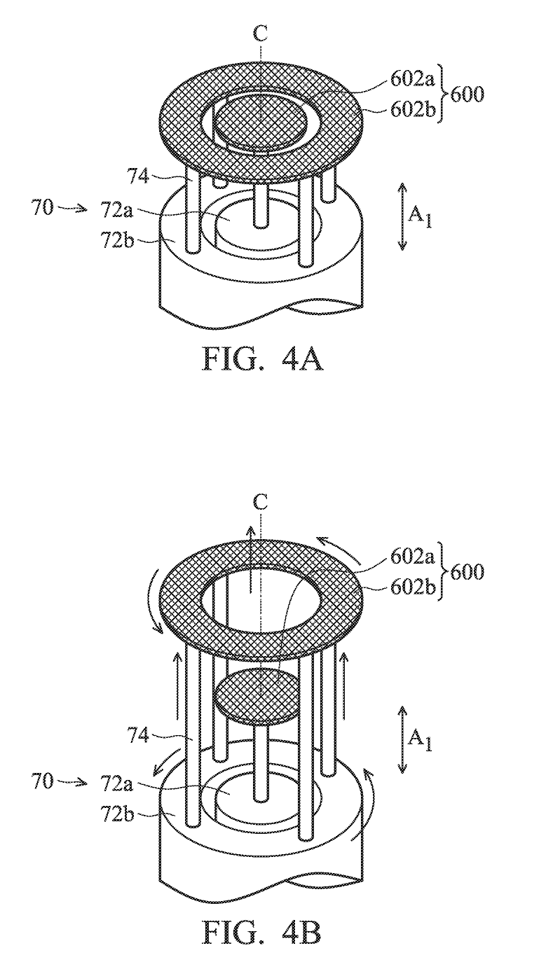

In some embodiments, the power electrodes 602a and 602b received in the hollow space 102a are movable relative to each other. Referring to FIG. 3, the distances between the top surface 202a of the dielectric body 200 and each of the power electrodes 602a and 602b are adjustable by independently moving the power electrodes 602a and 602b along the first axis A1. For example, a distance D along the first axis A1 is between the power electrode 602a and the top surface 202a, and a distance D′ along the first axis A1 is between the power electrode 602b and the top surface 202a. The power electrodes 602a and 602b are moved by the driving mechanism 70 (as shown in FIG. 4) through the openings 104a of the stage 100 in some embodiments.

Accordingly, the different distances between the top surface 202a and each of the power electrodes 602a and 602b can affect the plasma density distribution in the processing chamber 10. For example, the power electrode 602b which is closer to the top surface 202a relative to the power electrode 602a can increase the density of the plasma P above the edge of the substrate S. Therefore, the uniformity of the plasma density in the processing chamber 10 can be improved.

In some embodiments, the stage 100 is made of insulating or dielectric material, such as ceramic. In some embodiments, the stage 100 and the dielectric body 200 are made of the same material. In some embodiments, the dielectric body 200 and the stage 100 are integrally formed in one piece. In some embodiments, the power electrodes 602a and 602b are made of conductive material, such as metal.

FIG. 4A and FIG. 4B are schematic diagrams of the electrode unit 600 in FIG. 3 and the driving mechanism 70 in FIG. 1, in accordance with some embodiments. Referring to FIG. 4A and FIG. 4B, as the substrate S has a circular structure, the power electrodes 602a and 602b of the electrode unit 600 can be accordingly arranged in a concentric manner, in accordance with some embodiments. For example, the power electrode 602a has a circular-plate structure and the power electrode 602b has an annular-plate structure with the power electrode 602a disposed therein. However, it should be appreciated that embodiments of the disclosure are not limited thereto. In some embodiments, the power electrodes 602a and/or 602b have other type structures, such as rectangular structure, polygonal structure, or irregular structure.

In some embodiments, the driving mechanism 70 includes cylinders 72a, 72b, and pins 74 connecting the cylinders 72a and 72b with the power electrodes 602a and 602b. Referring to FIG. 4B, the power electrode 602b can move vertically along a central axis C (parallel to the first axis A1) of the electrode unit 600 by the pins 74. Also, the power electrode 602b can rotate along the central axis C by the cylinder 72b and the pins 74. In some embodiments, the driving mechanism 70 also includes motor, roller, belt, or a combination thereof, which can drive the electrode unit 600 to move or rotate.

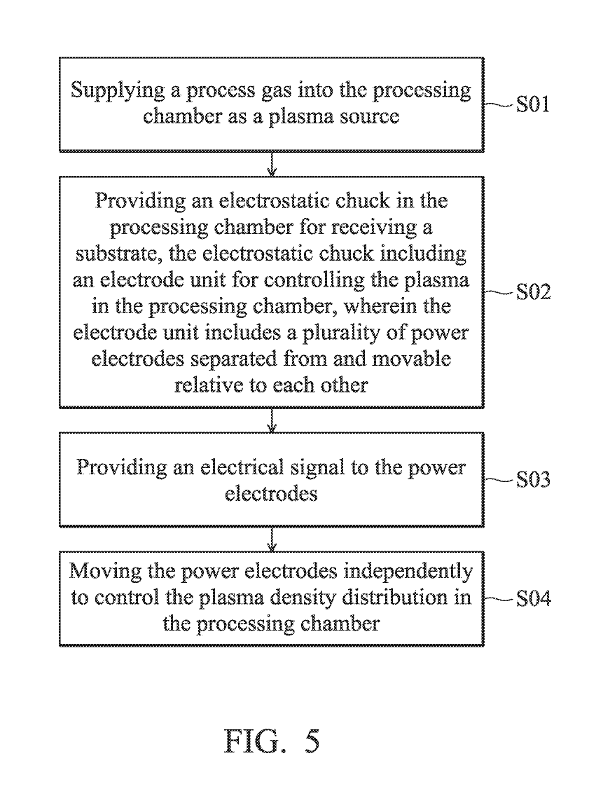

Embodiments of a method for controlling the plasma density distribution in a processing chamber are also provided. FIG. 5 is a flow chart of a plasma-uniformity control method, in accordance with some embodiments of the disclosure. In operation S01, a process gas is supplied into a processing chamber as a plasma source. In some embodiments, the processing chamber is formed in a plasma processing apparatus, such as a plasma etching apparatus or PECVD apparatus.

In operation S02, an electrostatic chuck is provided. The electrostatic chuck is positioned in the processing chamber, and can be used to secure a substrate, such as a semiconductor wafer, by applying an electrostatic attraction force. In some embodiments, the electrostatic chuck includes a power unit having a number of power electrodes separated from and movable relative to each other. In some embodiments, the dimensions of the electrode unit correspond to those of the substrate. In some embodiments, the shape of the electrode unit corresponds to that of the substrate.

In operation S03, the power electrodes are provided with an electrical signal. In some embodiments, the power electrodes are driven by a single electrical signal for controlling the plasma in the processing chamber. In some embodiments, the power electrodes are driven by different electrical signals. The electrical signals may be RF signals or DC signals.

In operation S04, the power electrodes are moved independently to control the plasma density distribution in the processing chamber. In some embodiments, the power electrodes are movable along a central axis of the electrode unit or rotatable along the central axis. In some embodiments, the distances between the plasma and each of the power electrodes are adjustable by independently moving the power electrodes.

Since the distances between the plasma and each of the power electrodes can be adjustable by independently moving the power electrodes, the plasma density in the processing chamber can be tunable by zone. Therefore, the uniformity of the plasma density in the processing chamber can be improved.

Embodiments of a plasma density distribution control method and a plasma processing apparatus are provided. The plasma processing apparatus includes an electrostatic chuck positioned in a processing chamber thereof. The electrostatic chuck includes a number of power electrodes for controlling the plasma in the processing chamber, and the power electrodes are separated from and movable relative to each other. Since the distances between the plasma and each of the power electrodes are adjustable, the plasma density in the processing chamber can thus be tunable by zone. Therefore, the uniformity of the plasma density in the processing chamber can be improved. Further, the power electrodes can be driven by single electrical signal. Therefore, the cost and system complexity of the plasma processing apparatus can be reduced.

In some embodiments, a method for controlling the plasma density distribution in a processing chamber is provided. The method includes supplying a process gas into the processing chamber as a plasma source. The method also includes receiving a substrate by using an electrostatic chuck in the processing chamber. The electrostatic chuck includes an electrode unit for controlling the plasma in the processing chamber, and the electrode unit includes a number of power electrodes separated from and movable relative to each other. The method further includes moving the power electrodes independently to control the plasma density distribution in the processing chamber.

In some embodiments, an electrostatic chuck is provided. The electrostatic chuck includes a stage and a dielectric body positioned on the stage. The dielectric body is configured to receive a substrate. The electrostatic chuck also includes an electrode positioned in the dielectric body and configured to apply an electrostatic attraction to the substrate. The electrostatic chuck further includes an electrode unit positioned in the stage, and the electrode unit includes a number of power electrodes separated from and movable relative to each other.

In some embodiments, a plasma processing apparatus is provided. The plasma processing apparatus includes a processing chamber. The plasma processing apparatus also includes a gas-supply configured to supply a process gas into the processing chamber as a plasma source. The plasma processing apparatus further includes an electrostatic chuck positioned in the processing chamber. The electrostatic chuck includes a stage and a dielectric body positioned on the stage. The dielectric body is configured to receive a substrate. The electrostatic chuck also includes an electrode positioned in the dielectric body and configured to apply an electrostatic attraction to the substrate. The electrostatic chuck further includes an electrode unit positioned in the stage, and the electrode unit includes a number of power electrodes separated from and movable relative to each other.

Although embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps. In addition, each claim constitutes a separate embodiment, and the combination of various claims and embodiments are within the scope of the disclosure.

What is claimed is:

1. A method for controlling the plasma density distribution in a processing chamber, comprising:
supplying a process gas into the processing chamber as a plasma source;
receiving a substrate by using an electrostatic chuck in the processing chamber, wherein the electrostatic chuck includes an electrode unit for controlling the plasma in the processing chamber, and the electrode unit includes a plurality of power electrodes separated from and movable relative to each other; and
moving the power electrodes independently to control the plasma density distribution in the processing chamber.

2. The method as claimed in claim 1, wherein the distances between the plasma and each of the power electrodes are adjustable by independently moving the power electrodes.

3. The method as claimed in claim 1, wherein the power electrodes are movable along a central axis of the electrode unit or rotatable along the central axis.

4. The method as claimed in claim 1, wherein the dimensions of the electrode unit correspond to those of the substrate.

5. The method as claimed in claim 1, wherein the shape of the electrode unit corresponds to that of the substrate.

6. The method as claimed in claim 5, wherein the power electrodes of the electrode unit are arranged in a concentric manner.

7. The method as claimed in claim 1, wherein the power electrodes are driven by a single electrical signal for controlling the plasma density distribution in the processing chamber.

8. The method as claimed in claim 7, wherein the single electrical signal is a radio frequency (RF) signal or direct current (DC) signal.

9. The method as claimed in claim 1, wherein the power electrodes are driven by different electrical signals for controlling the plasma density distribution in the processing chamber.

10. The method as claimed in claim 9, wherein the electrical signals are radio frequency (RF) signals or direct current (DC) signals.

11. An electrostatic chuck, comprising:
a stage;
a dielectric body positioned on the stage and configured to receive a substrate;
an electrode positioned in the dielectric body and configured to apply an electrostatic attraction to the substrate; and
an electrode unit positioned in the stage, including a plurality of power electrodes separated from and movable relative to each other.

12. The electrostatic chuck as claimed in claim 11, further comprising a hollow space in the stage, wherein the power electrodes are movably received in the hollow space.

13. The electrostatic chuck as claimed in claim 11, wherein the distances between a top surface of the dielectric body and each of the power electrodes are adjustable by independently moving the power electrodes relative to the stage.

14. The electrostatic chuck as claimed in claim 11, wherein the dimensions and/or shape of the electrode unit correspond to those of the substrate.

15. The electrostatic chuck as claimed in claim 11, wherein the stage comprises a dielectric material.

16. A plasma processing apparatus, comprising:
a processing chamber;
a gas-supply configured to supply a process gas into the processing chamber as a plasma source; and
an electrostatic chuck positioned in the processing chamber, wherein the electrostatic chuck comprises:
a stage;
a dielectric body positioned on the stage and configured to receive a substrate;
an electrode positioned in the dielectric body and configured to apply an electrostatic attraction to the substrate; and
an electrode unit positioned in the stage, including a plurality of power electrodes separated from and movable relative to each other.

17. The plasma processing apparatus as claimed in claim 11, further comprising a driving mechanism configured to independently move the power electrodes relative to the stage, such that the distances between the plasma and each of the power electrodes are adjustable.

18. The plasma processing apparatus as claimed in claim 17, wherein the power electrodes are movable along a central axis of the electrode unit or rotatable along the central axis.

19. The plasma processing apparatus as claimed in claim 11, further comprising an electrical power supply configured to apply a single radio frequency (RF) signal or direct current (DC) signal to the power electrodes for controlling the plasma density distribution in the processing chamber.

20. The plasma processing apparatus as claimed in claim 11, further comprising a fluid-supply configured to provide a fluid to the electrostatic chuck.
